(19) United States
(12) Patent Application Publication
(10) Pub. No.: US 2009/0066237 A1
(43) Pub. Date: Mar. 12, 2009

(54) ORGANIC ELECTROLUMINESCENT DEVICE, FABRICATION PROCESS OF ORGANIC ELECTROLUMINESCENT DEVICE, DISPLAY DEVICE, AND FABRICATION PROCESS OF DISPLAY DEVICE

(75) Inventors: Emiko Kambe, Kanagawa (JP); Tadahiko Yoshinaga, Kanagawa (JP); Yasunori Kijima, Tokyo (JP); Mitsuhiro Kashiwabara, Kanagawa (JP); Hirokazu Yamada, Aichi (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(73) Assignee: SONY CORPORATION, Tokyo (JP)

(21) Appl. No.: 12/207,115

(22) Filed: Sep. 9, 2008

(30) Foreign Application Priority Data
Sep. 12, 2007 (JP) 2007-236193

(51) Int. Cl. H01J 1/62; B05D 5/12

(52) U.S. Cl. 313/504; 427/66

(57) ABSTRACT

An organic electroluminescent device is provided with a substrate, and a lower electrode, a luminescence function layer including an organic light-emitting layer, and an upper electrode stacked in this order on the substrate to emit light, which has been generated in said organic light-emitting layer, out of said upper electrode. The lower electrode includes a reflective material layer comprised essentially of metal, an oxide film provided on a surface of said reflective material layer, and a thin metal film provided over the oxide film.

### CROSS REFERENCES TO RELATED APPLICATIONS

The present invention contains subject matter related Japanese Patent Application JP 2007-236193 filed in the Japan Patent Office on Sep. 12, 2007, the entire contents of which being incorporated herein by reference.

### BACKGROUND OF THE INVENTION

1. Field of the Invention

This invention relates to a surface-emitting, organic electroluminescent device and its fabrication process, and also to a display device making use of a plurality of such organic electroluminescent devices and its fabrication process.

2. Description of the Related Art

As one type of flat panel displays, display devices each making use of organic electroluminescent devices are attracting attention. An organic electroluminescent device is a self-emitting device making use of organic electroluminescence, and is equipped, between two electrodes, with a luminescence function layer which includes an organic light-emitting layer. A display device making use of a plurality of such organic electroluminescent device is excellent for its wide viewing angle, small power consumption and light weight.

Fabrication of an organic electroluminescent device can be conducted as illustrated in FIGS. 10A through 10D, which are cross-sectional views of the organic electroluminescent device in various stages of a conventional fabrication process. As illustrated in FIG. 10A, an anode 202 is first formed in a predetermined pattern as a lower electrode on a substrate 201. As shown in FIG. 10B, a window insulating film 203 equipped with a pixel opening is next formed such that the anode 202 is covered at peripheral edges thereof but is exposed at a central part thereof. As depicted in FIG. 10C, a luminescence function layer 204 equipped with an electron-transporting, organic light-emitting layer (not shown) is then formed on the anode 202 exposed in the pixel opening of the window insulating film 203. Although not illustrated in FIG. 3C, the luminescence function layer 204 is composed, for example, of a hole injection layer, a hole transport layer and the organic light-emitting layer stacked from the side of the anode 202. As shown in FIG. 10D, a cathode 205 is subsequently formed as an upper electrode on the luminescence function layer 204.

In the organic electroluminescent device EL obtained as described above, light is generated upon recombination of electrons injected from the cathode 205 with holes injected from the anode 202 in the organic light-emitting layer of the luminescence function layer 204. The thus-generated light is outputted from the side of the substrate 201 or the side of the cathode 205.

In an active matrix display device, organic electroluminescent devices are arranged on a TFT substrate on which thin-film transistors (hereinafter referred to as “TFTs”) are formed for driving pixels. For an improvement in the aperture rate of a light-emitting portion, it is hence advantageous to form each organic electroluminescent device in the so-called surface-emitting device structure that generated light is outputted from the side opposite to the substrate 201.

In a surface-emitting, organic electroluminescent device, on the other hand, it is a common practice to use a high-reflectivity anode and to form a cavity structure. In a cavity structure, the thickness of a luminescence function layer is specified by the wavelength of an emission, and can be determined from a calculation of multiple interference. In such a surface-emitting device structure, positive use of the cavity structure makes it possible to improve the efficiency of light output to the outside and the control of an emission spectrum.

As a material that forms such a high-reflectivity anode, it has been proposed to use, for example, silver (Ag) or a silver-containing alloy (see JP-A-2003-77681 and JP-A-2003-234193). In addition, the use of an aluminum(Al) alloy containing copper(Cu), palladium(Pa), gold(Au), nickel(Ni) or platinum(Pt) as an auxiliary metal component has also been proposed (see JP-A-2003-234193).

As a method for improving the hole injection characteristic when an anode made of such a metal material is used, it has also been proposed to adopt such a construction that a hole injection layer, which is in contact with the anode, is doped with a metal oxide such as V₂O₅ (see JP-A-2007-5784).

### SUMMARY OF THE INVENTION

In the fabrication process of an organic electroluminescent device, however, the formation of an anode and the formation of a light-emitting layer are not conducted successively in an vacuum atmosphere. For example, as described with reference to FIGS. 10A through 10D, a lithographic step is performed in a non-vacuum atmosphere to form the window insulating film 203 subsequent to the formation of the lower electrode 202. In the course of the formation of the window insulating film 203, an oxide film is unavoidably formed by natural oxidation on the surface of the anode made of a metal material.

As a consequence, the injection of holes from the anode into the luminescence function layer is effected primarily from the oxide film. This prevents the injection of holes from the anode into the luminescence function layer, and therefore, has become a cause of a substantial increase in drive voltage.

Therefore, it is desirable to provide an organic electroluminescent device of a surface-transmitting construction making use of a high-reflectivity lower electrode, said organic electroluminescent device being capable of achieving an improved luminescence efficiency, and also a fabrication process of the same.

To achieve the above-described desire, an embodiment of the present invention provides an organic electroluminescent device provided with a substrate, and a lower electrode, a luminescence function layer including an organic light-emitting layer, and an upper electrode stacked in this order on the substrate to emit light, which has been generated in the organic light-emitting layer, out of the upper electrode. The lower electrode includes a reflective material layer including a metal material, an oxide film provided on a surface of the reflective material layer, and a thin metal film provided over the oxide film.

Another embodiment of the present invention provides a fabrication process of an organic electroluminescent device, which includes a first step of forming a reflective material layer in a predetermined pattern comprised essentially of metal on a substrate, a second step of successively forming a thin metal film and a luminescence function layer in this order on the reflective material layer in an inert atmosphere, and a third step of forming an upper electrode on the luminescence function layer.

According to the above-described construction, the oxide film on the surface of the reflective material layer is covered with the thin metal film. Therefore, the thin metal film acts as a layer that forms the outermost surface of the lower electrode, and charges (for example, holes) are injected from the thin metal film into the luminescence function layer. As a consequence, it is possible to maintain high the efficiency of injection of charges from the high-reflectivity lower electrode into the luminescence function layer in the construction that the thin metal film has been formed as a result of natural oxidation of the surface of the reflective material layer.

According to the embodiments of the present invention, the efficiency of injection of charges from the lower electrode into the luminescence function layer can be maintained high in the surface-emitting construction making use of the high-reflectivity lower electrode. It is, therefore, possible to achieve both an improvement in emission efficiency and a reduction in drive voltage in the surface-emitting organic electroluminescent device. As a consequence, improvements can be made in the service life characteristics of the organic electroluminescent device.

### BRIEF DESCRIPTION OF THE DRAWINGS

FIG. 1A is a fragmentary cross-sectional view of a display device making use of a plurality of organic electroluminescent devices according to an embodiment the present invention, and FIG. 1B is a cross-sectional view of one of the organic electroluminescent devices;

FIGS. 2A through 2D are fragmentary cross-sectional views of the organic electroluminescent device according to the embodiment of the present invention and/or the display device in various stages of their fabrication processes;

FIG. 3 is a circuit construction diagram of the display device according to the embodiment of the present invention;

FIG. 4 is a construction diagram depicting a modularized display device of a sealed construction, to which the present invention can be applied;

FIG. 5 is a perspective view showing a television set to which the present invention can be applied;

FIG. 6A is a perspective view illustrating a digital camera, to which the present invention can be applied, as viewed from a front side, and FIG. 6B is a perspective view of the digital camera as viewed from a back side;

FIG. 7 is a perspective view depicting a notebook-size personal computer to which the present invention can be applied;

FIG. 8 is a perspective view depicting a video camera to which the present invention can be applied;

FIG. 9A is a front view of a cellular phone as an example of mobile terminal equipment, to which the present invention can be applied, in an opened state, FIG. 9B is a side view of the cellular phone in the opened state, FIG. 9C is a front view of the cellular phone in a closed state, FIG. 9D is a left side view of the cellular phone in the closed state, FIG. 9E is a right side view of the cellular phone in the closed state, FIG. 9F is a top view of the cellular phone in the closed state, and FIG. 9G is a bottom view of the cellular phone in the closed state; and

FIGS. 10A through 10D are cross-sectional views of an organic electroluminescent device in various stages of an existing fabrication process.

### DETAILED DESCRIPTION OF THE PREFERRED EMBODIMENTS

With reference to the accompanying drawings, preferred embodiments of the present invention will hereinafter be described in detail in the order of the constructions of an organic electroluminescent device and a display device, and their fabrication processes.

### <<Constructions of Organic Electroluminescent Device and Display Device>>

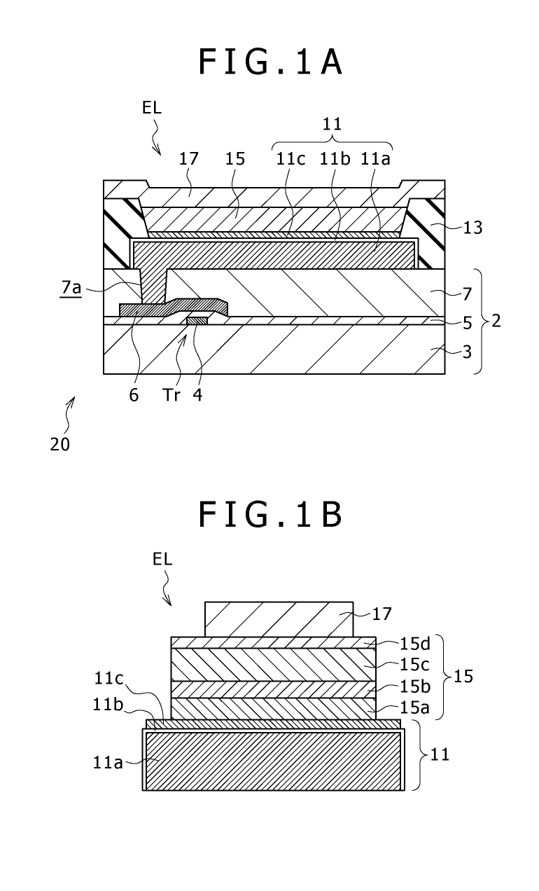

FIG. 1A is a cross-sectional view schematically illustrating one of pixels in a display device 20 making use of organic electroluminescent devices EL according to the embodiment of the present invention, and FIG. 1B is a cross-sectional view depicting the construction of one of the organic electroluminescent devices EL. The display device 20 illustrated in FIG. 1A is, for example, an active matrix display device, and is provided with the organic electroluminescent devices EL on a TFT substrate 2 on which thin-film transistors Tr are formed. The construction of the display device 20 will hereinafter be described element by element from a lower side.

The TFT substrate 2 includes a substrate 3 and thin layer transistors Tr arranged on the substrate 3. The substrate 3 can be selected from a transparent substrate such as a glass substrate, a silicon substrate, a film-shaped flexible substrate or the like as desired. Each thin layer transistor Tr has been formed by stacking a gate electrode 4, a gate insulating film 5 and a semiconductor layer 6 in this order on the substrate 3. The substrate 3 with the thin layer transistor Tr arranged thereon is covered by a planarization insulating film 7.

Each organic electroluminescent device EL arranged on the TFT substrate 2 of the above-described construction is a surface-emitting device that generated light is outputted from a side opposite to the TFT substrate 2, and is composed of a lower electrode 11, a window insulating film 13 covering the lower electrode 11 at peripheral edges thereof, a luminescence function layer 15 on the lower electrode 11, and an upper electrode 17 on the luminescence function layer 15, which are arranged in this order from the side of the TFT substrate 2.

The embodiment of the present invention has the construction of the lower electrode 11 and the construction of the luminescence function layer 15 arranged in contact with the lower electrode 11. The construction of the organic electroluminescent device EL of the above-described construction will hereinafter be described element by element from the side of the TFT substrate 2.

<Lower Electrode 11>The lower electrode 11 is composed of a reflective material layer 11a made of metal, an oxide film 11b provided on a surface of the reflective material layer 11a, and a thin metal film 11c covering the reflective material layer 11a on which the oxide film 11b is provided.

Of these elements, the reflective material layer 11a is not only a light reflecting layer but also a layer for allowing the lower electrode 11 to act as an anode or a cathode. In this embodiment, it is assumed, for example, that the lower electrode 11 is allowed to act as an anode. This reflective material layer 11a is formed of a high-reflectivity metal material. Usable examples of the high-reflectivity metal material include aluminum(Al), alloys such as aluminum(Al)-neodymium(Nd), silver(Ag), silver(Ag) alloys, nickel(Ni), molybdenum(Mo), chromium(Cr), gold(Au), and platinum(Pt).

The oxide film 11b provided on the surface of the reflective material layer 11a is a natural oxidation film formed on the surface of the reflective material layer 11a, and includes one formed on a part of the surface of the reflective material layer 11a. When the reflective material layer 11a is formed of an alloy, the oxide film 11b can be in such a form that only one or some of its metals are oxidized at its or their surfaces.

The thin metal film 11c, which covers the reflective material layer 11a with the oxide film 11b provided thereon, is a film which is employed as a modifying layer for the lower electrode 11. This thin metal film 11c can be formed of a stable metal material irrespective of whether the lower electrode 11 is an anode or a cathode. Aluminum(Al) or copper(Cu) is particularly preferred from the viewpoint of long service life. This thin metal film 11c can be an extremely thin film, and is assumed to have, for example, a thickness of from 0.1 nm to 3 nm or so. The setting of its thickness at 0.1 nm or greater can sufficiently bring about the modifying effects for the lower electrode 11 owing to the arrangement of the thin metal film 11c. The setting of its thickness at 3 nm or smaller, on the other hand, makes it possible to maintain light reflectivity at the reflective material layer 11a and, when the organic electroluminescent device EL is constructed in a resonator structure, to fully exhibit the microcavity effect and hence, to maintain improved color purity and luminescence efficiency.

The lower electrode 11 is assumed to be arranged as a patterned pixel electrode for its corresponding pixel provided with the thin-film transistor Tr. This lower electrode 11 is also assumed to be connected to a source/drain arranged in the semiconductor layer 6 of the thin-film transistor Tr via a corresponding connection hole 7a formed in the planarization insulating film 7 of the TFT substrate 2.

### <Window Insulating Film 13>

The window insulating film 13 covers the respective lower electrodes 11 which are formed in arrays on the TFT substrate 2, at peripheral edges thereof. Portions of the window insulating film 13, in which the lower electrodes 11 are exposed, respectively, are pixel openings.

### <Luminescence Function Layer 15>

The luminescence function layer 15 is constructed including at least an organic light-emitting layer 15c. As one construction example of the luminescence function layer 15, a hole injection layer 15a, a hole transport layer 15b, the organic light-emitting layer 15c and a electron transport layer 15d are stacked in this order out of the anode (in this embodiment, the lower electrode 11).

The hole injection layer 15a is a layer which is in contact with the lower electrode 11, and has a characteristic construction in the present invention. Specifically, this hole injection layer 15a can be formed preferably with a material having electron-accepting property.

As a compound which can function as an electron-accepting material, one capable of oxidizing an organic material as a Lewis acid catalyst can be mentioned. Specific usable examples include, but are not limited to, metal oxides such as nickel oxide, vanadium oxide, molybdenum oxide, rhenium oxide and tungsten oxide, inorganic compounds such as ferric chloride, ferric bromide, ferric iodide, aluminum iodide, gallium chloride, gallium bromide, gallium iodide, indium chloride, indium bromide, indium iodide, antimony pentachloride, arsenic pentafluoride and boron trifluoride, and organic compounds such as DDQ (dicyano-dichlorquinone), TNF (trinitrofluorenone), TCNQ (tetracyanoquinodimethane), 4F-TCNQ (tetrafluoro-tetracyanoquinodimethane) and HAT (hexanitrile hexaazatriphenylene).

The hole injection layer 15a may particularly preferably be formed by using a material represented by the following formula (1) as a compound which functions as an electron accepting material.

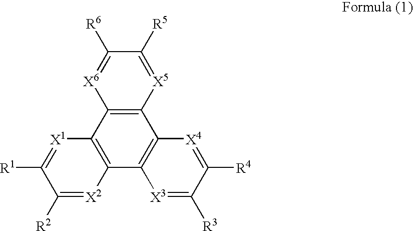

wherein R¹ to R⁶ each independently represent a hydrogen atom, or a substituent selected from a halogen atom, a hydroxyl group, an amino group, an arylamino group, a substituted or unsubstituted carbonyl group having not greater than 20 carbon atoms, a substituted or unsubstituted carbonyl ester group having not greater than 20 carbon atoms, a substituted or unsubstituted alkyl group having not greater than 20 carbon atoms, a substituted or unsubstituted alkenyl group having not greater than 20 carbon atoms, a substituted or unsubstituted alkoxyl group having not greater than 20 carbon atoms, a substituted or unsubstituted aryl group having not greater than 30 carbon atoms, a substituted or unsubstituted heterocyclic group having not greater than 30 carbon atoms, a nitrile group, a nitro group, a cyano group, or silyl group, adjacent R^{m} (m: 1 to 6) may be fused together to form ring structures together with the associated carbon atoms of the corresponding 6-membered rings, respectively, and X¹ to X⁶ each independently represent a carbon or nitrogen atom.

As specific examples of triphenylene derivatives and azatriphenylene derivatives represented by the formula (1), the compounds of the formulas (1)-1 to (1)-64 shown below in Table 1 to Table 7 can be exemplified. In these formulas, “Me” represents a methyl group (CH₃) and “Et” represents an ethyl group (C₂H₅) . Further, the structural formulas (1)-61 to (1)-64 exemplify organic compounds of the formula (1) in which among R¹ to R⁶, adjacent R^{m} (m: 1 to 6) are fused together to form ring structures together with the associated carbon atoms of the corresponding 6-membered rings, respectively,

TABLE 1

| | |
|---|---|
| | Structural formula (1)-1 |
| 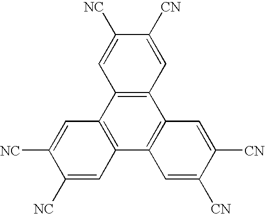 | |
| | Structural formula (1)-2 |
| 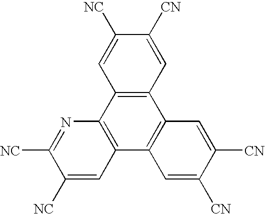 | |
| | Structural formula (1)-3 |
| 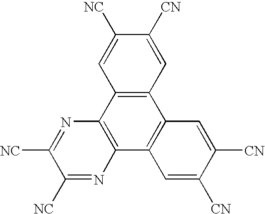 | |
| | Structural formula (1)-4 |
| 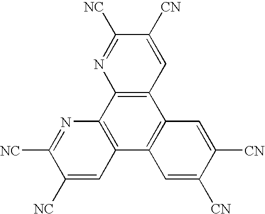 | |
| | Structural formula (1)-5 |
| 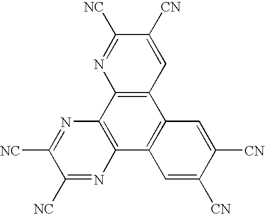 | |
| | Structural formula (1)-6 |
| 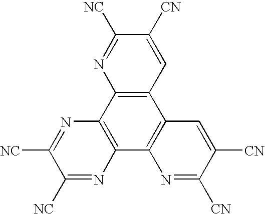 | |
| | Structural formula (1)-7 |
| 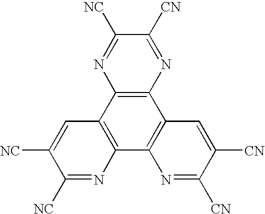 | |
| | Structural formula (1)-8 |
| 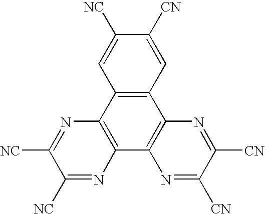 | |
| | Structural formula (1)-9 |
| 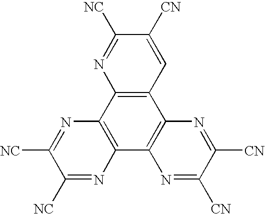 | |
| | Structural formula (1)-10 |
| 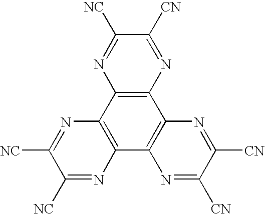 | |

TABLE 2

| | |
|---|---|
| | Structural formula (1)-11 |
| 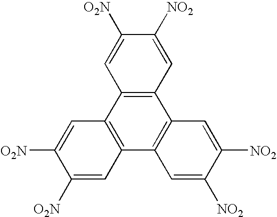 | |
| | Structural formula (1)-12 |
| 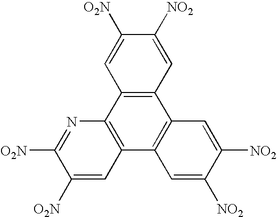 | |
| | Structural formula (1)-13 |
| 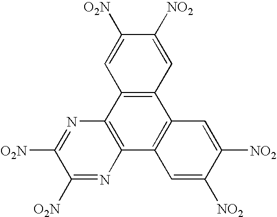 | |
| | Structural formula (1)-14 |
| 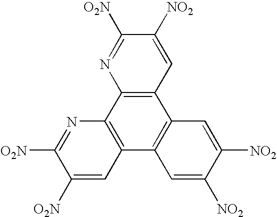 | |
| | Structural formula (1)-15 |
| 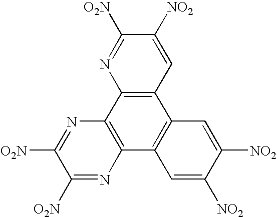 | |
| | Structural formula (1)-16 |
| 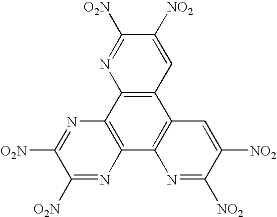 | |
| | Structural formula (1)-17 |
| 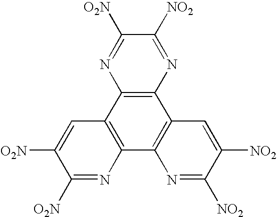 | |
| | Structural formula (1)-18 |
| 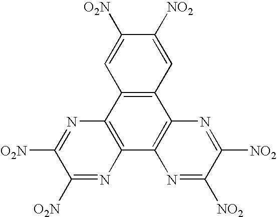 | |
| | Structural formula (1)-19 |
| 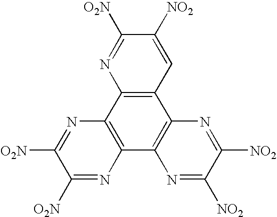 | |
| | Structural formula (1)-20 |
| 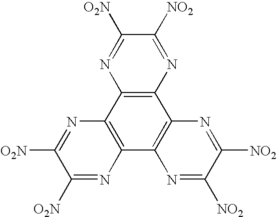 | |

TABLE 3

| | |
|---|---|
| | Structural formula (1)-21 |
| 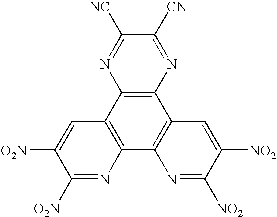 | |
| | Structural formula (1)-22 |
| 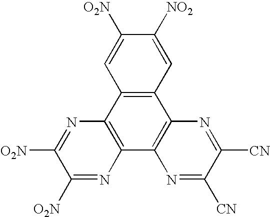 | |
| | Structural formula (1)-23 |
| 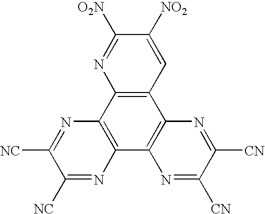 | |
| | Structural formula (1)-24 |
| 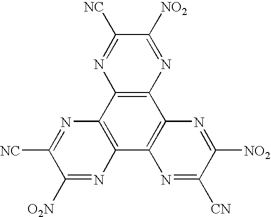 | |
| | Structural formula (1)-25 |
| 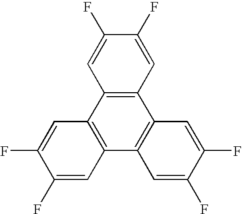 | |
| | Structural formula (1)-26 |
| 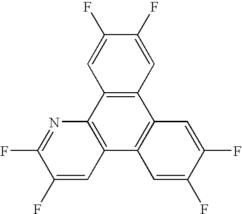 | |
| | Structural formula (1)-27 |
| 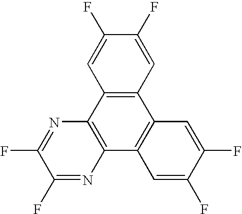 | |
| | Structural formula (1)-28 |
| 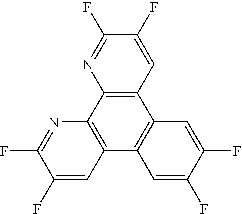 | |
| | Structural formula (1)-29 |
| 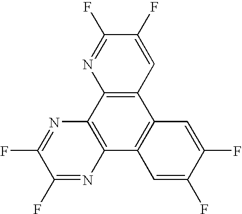 | |
| | Structural formula (1)-30 |
| 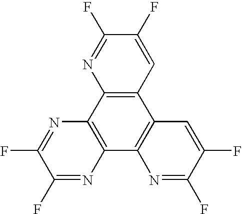 | |

TABLE 4

| | |
|---|---|
| | Structural formula (1)-31 |
| 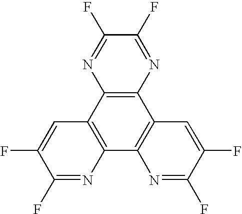 | |
| | Structural formula (1)-32 |
| 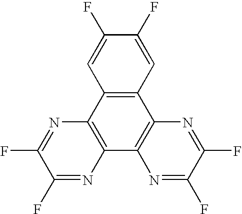 | |
| | Structural formula (1)-33 |
| 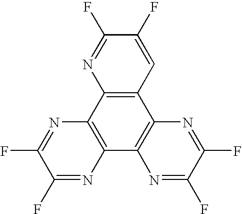 | |
| | Structural formula (1)-34 |
| 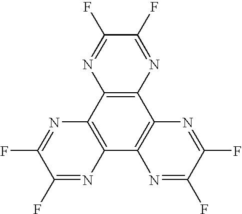 | |
| | Structural formula (1)-35 |
| 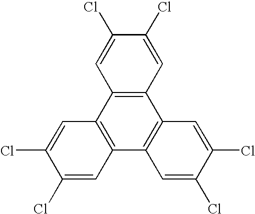 | |
| | Structural formula (1)-36 |
| 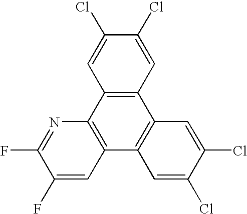 | |
| | Structural formula (1)-37 |
| 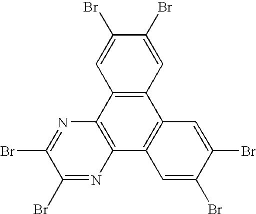 | |
| | Structural formula (1)-38 |
| 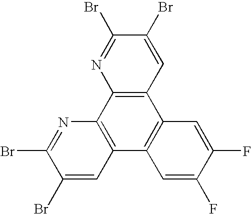 | |
| | Structural formula (1)-39 |
| 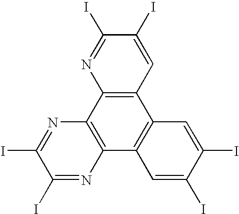 | |
| | Structural formula (1)-40 |
| 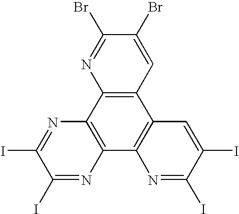 | |

TABLE 5

Structural formula (1)-41

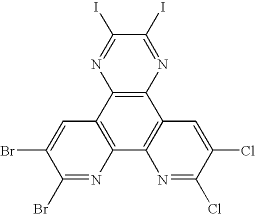

Structural formula (1)-42

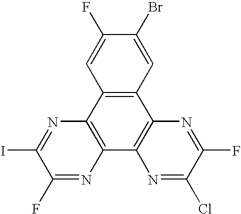

Structural formula (1)-43

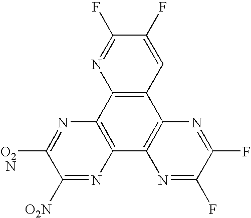

Structural formula (1)-44

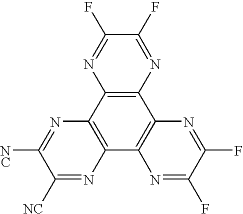

Structural formula (1)-45

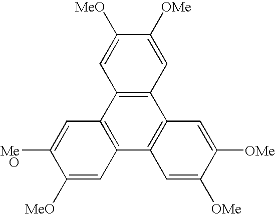

Structural formula (1)-46

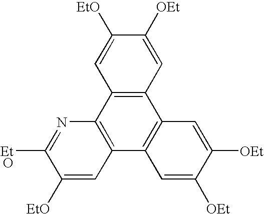

Structural formula (1)-47

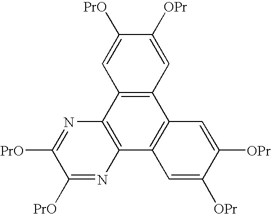

Structural formula (1)-48

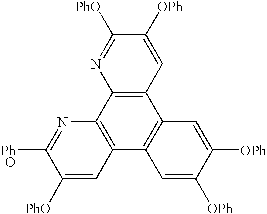

Structural formula (1)-49

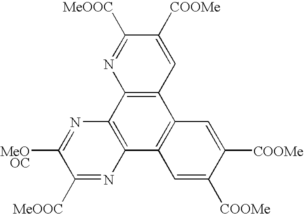

Structural formula (1)-50

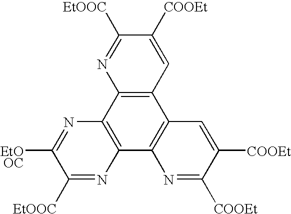

TABLE 6

Structural formula (1)-51

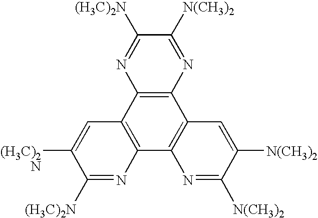

Structural formula (1)-52

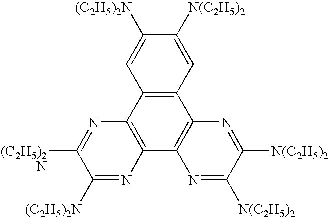

Structural formula (1)-53

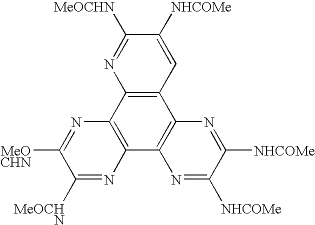

Structural formula (1)-54

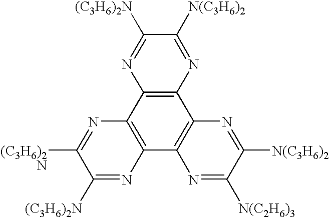

Structural formula (1)-55

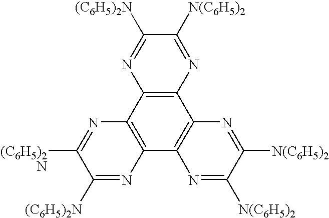

Structural formula (1)-56

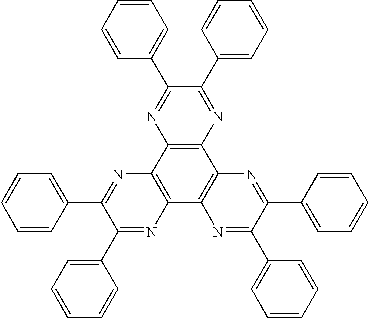

Structural formula (1)-57

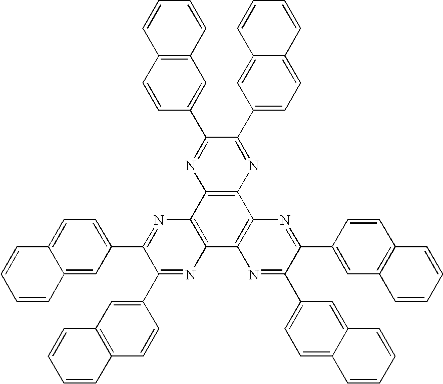

Structural formula (1)-58

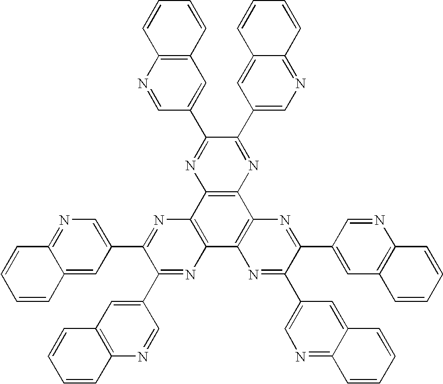

Structural formula (1)-59

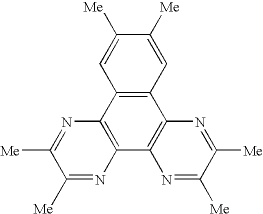

Structural formula (1)-60

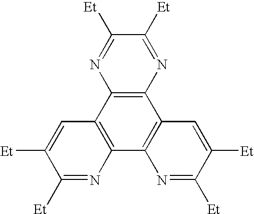

TABLE 7

Structural formula (1)-61

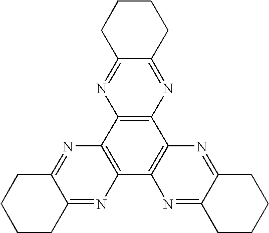

Structural formula (1)-62

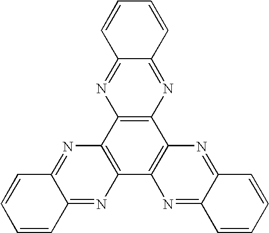

Structural formula (1)-63

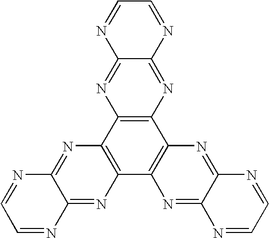

Structural formula (1)-64

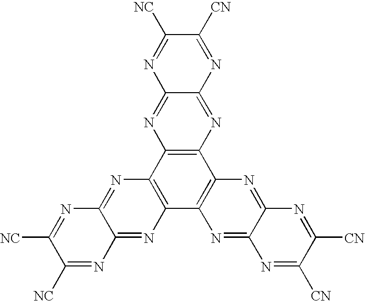

The hole transport layer 15b is arranged to increase the injection efficiency of holes into the organic light-emitting layer 15c. Usable examples of a material for the hole transport layer 15b include monomers, oligomers and polymers of benzine, styrylamine, triphenylamine, porphyrin, triphenylene, azatriphenylene, tetracyanoquinodimethane, triazole, imidazole, oxadiazole, polyarylalkanes, phenylenediamine, arylamines, oxazole, fullerene, anthracene, fluorenone, hydrazone and stilbene, derivatives thereof, polysilane compounds, and conjugated cyclic compounds such as vinylcarbazole compounds, thiophene compounds and aniline compounds.

The organic light-emitting layer 15c may contain a fluorescent dye as a luminescent dopant. The luminescent dopant can be selected, for example, from fluorescent materials such as laser dyes, e.g., styrylbenzene dyes, oxazole dyes, perylene dyes, coumarin dyes and acridine dyes, polyaromatic hydrocarbon materials, e.g., anthracene derivatives, naphthacene derivatives, pentacene derivatives and chrysene derivatives, pyrromethene skeleton compounds and metal complexes thereof, quinacridone derivatives, DCM, DCJTB, BSB-BCN, SP, benzothiazole compounds, benzoimidazole compounds and metal-chelated oxynoid compounds. Such a fluorescent material may desirably be at a dope concentration of 0.1% or higher but 50% or lower in view of its concentration quenching as a dopant.

The electron transport layer 15d is formed of a material having low LUMO to reduce the barrier for electrons injected from the cathode. Examples of such a material include quinoline, perylene, phenanthroline, bisstyryl, pyrazine, triazole, oxazole, oxadiazole, fluorenone, and their derivatives and metal complexes. Specific examples include tris(8-hydroxyquinoline)aluminum (abbreviated as “Alq3”), anthracene, naphthalene, phenanthroline, pyrene, anthracene, perylene, butadiene, coumarin, acridine, stilbene, 1,10-phthanthroline, and their derivatives and metal complexes.

It is to be noted that the luminescence function layer 15 is not limited to such a layered structure and another stacked structure may be chosen as desired.

For example, the organic light-emitting layer 15c may be an electron-transporting, organic light-emitting layer which also acts as an electron transport layer, or may be a hole-transporting, organic light-emitting layer. Further, the layers 15a to 15d may each have a stacked structure. Further, the organic light-emitting layer 15c may be, for example, a white-light-emitting layer formed of a blue-light-emitting portion, a green-light-emitting portion and a red-light-emitting portion.

Moreover, the luminescence function layer 15 may also be provided with one or more layers in addition to the above-mentioned, respective layers 15a to 15d. For example, an additional electron injection layer may be arranged on the electron transport layer 15d. Such an additional electron injection layer may contain one or more of alkali metals, alkaline earth metals, lanthanoid metals (La, Ce, Pr, Nd, Sm, Eu, Gd, Tb, Dy, Ho, Er, Tm, Yb, Lu), and their oxides, complex oxides and fluorides.

### <Upper Electrode 17>

The upper electrode 17 is constructed as a cathode when the lower electrode 11 is used as an anode, or is constructed as an anode in an opposite case. In this embodiment, the upper electrode 17 is constructed as a cathode. This upper electrode 17 is an electrode having light transmitting property.

The upper electrode 17 which acts as a cathode is formed, for example, of an alkaline earth metal such as Ca, an alkaline earth metal alloy such as MgAg, aluminum(Al), or the like. Use of a thin-film MgAg electrode or Ca electrode as the upper electrode 17 makes it possible to output light from the side of the upper electrode 17.

Especially when the organic electroluminescent device EL is constructed in a cavity structure that resonates light, which has been generated in the organic light-emitting layer 15c, and outputs the thus-resonated light from the side of the upper electrode 17, the upper electrode 17 is formed of a semi-reflective material. In this case, the upper electrode 17 may preferably be formed of a semi-reflective material such as, for example, MgAg.

The upper electrode 17 may preferably be formed in a double-layered structure with a layer, which is formed of a transparent lanthanoid oxide, stacked as a sealing electrode to inhibit deteriorations of the electrode.

The upper electrode 17 is not limited to such a double-layered structure. Needless to say, the upper electrode 17 may take a stacked structure of layers in a combination optimal for the structure of the device to be fabricated. For example, insofar as a stacked structure needed upon functional separation of the functions of the respective layers which form the upper electrode 17 is available, the upper electrode may be formed solely of a layer that functions as a cathode or a transparent electrode of ITO or the like may be additionally formed between a layer, which functions as a light-emitting layer, and the electrode.

The upper electrode 17 may also be used as a common electrode for plural organic electroluminescent devices EL arranged on the TFT substrate 2. In this case, the upper electrode 17 may be arranged in the form of a solid film over the entire surface of the TFT substrate 2 wile being kept insulated relative to the lower electrode 11 by the luminescence function layer 15 and the window insulating film 13. Although not illustrated in the figures, it is preferred to form auxiliary electrodes in the same layer as the lower electrodes 11 and to arrange the upper electrodes 17 in the form of a solid film such that the solid film is connected to the auxiliary electrodes.

### <Cavity Structure>

Now, assume that each organic electroluminescent device EL is formed in a cavity structure that outputs generated light subsequent to its resonation between the lower electrode 11 and the upper electrode 17. In this case, the optical distance L between the reflective material layer 11a in the lower electrode 11 and the semi-reflective layer forming the upper electrode 17 may preferably be a positive minimum value that satisfies the below-described equation (1).

2L/λ+φ/2π=q (1)

where,
λ: Wavelength of a peak in a spectrum of light to be outputted from the side of the upper electrode 17,
φ: Phase shift of reflected light occurring at reflecting surfaces of the lower electrode 11 and upper electrode 17.

### <<Fabrication Processes of Organic Electroluminescent Device and Display Device>>

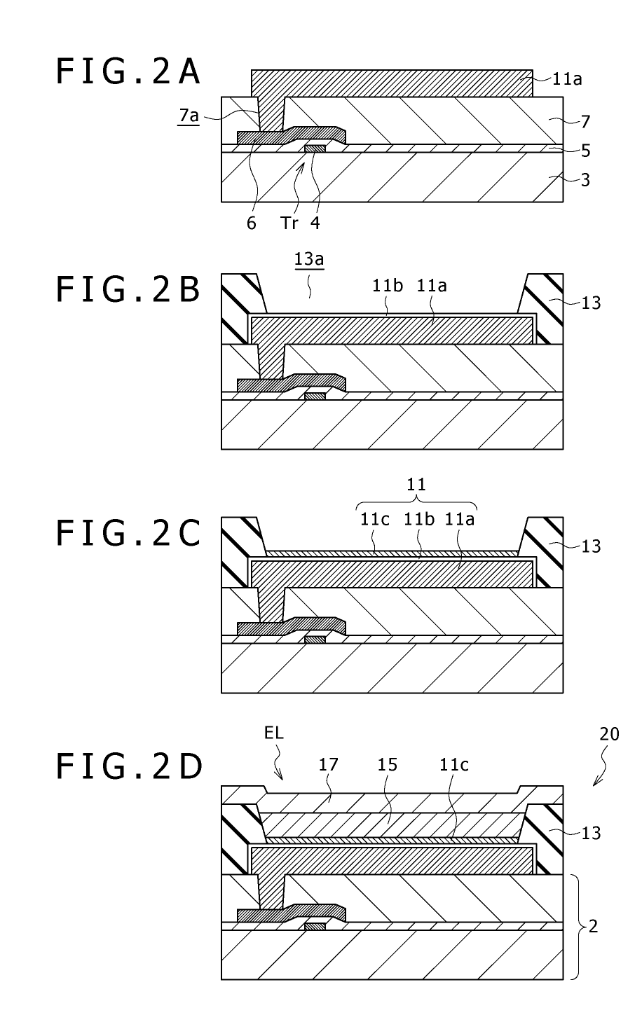

FIGS. 2A through 2D are fragmentary cross-sectional views of the above-described organic electroluminescent device and/or display device in various stages of their fabrication processes. Their fabrication processes will next be described with reference to these figures. It is to be noted that the description of the elements of structure already described above is omitted to avoid repetition.

As illustrated in FIG. 2A, gate electrodes 4 are first formed in a predetermined pattern on a substrate 3. The gate electrodes 4 are then covered with a gate insulating film 5, and a semiconductor layer 6 is formed in a predetermined pattern on the gate insulating film 5 to obtain thin-layer transistors Tr.

On the substrate 3 with the thin-film transistors Tr arranged thereon, a planarization insulating film 7 made of an insulating film of an organic material such as a polyimide or a silicon-based inorganic material is then formed. In the planarization insulating film 7, connection holes 7a are then formed extending to the sources/drains in the semiconductor layer 6. The formation of the connection holes 7a is conducted in a general lithographic step.

On the planarization insulating film 7, a reflective material layer 11a is then formed in a predetermined pattern such that it is connected to the sources/drains in the semiconductor layer 6 via the connection holes 7a. The reflective material layer 11a should be formed in the shape of the pixel electrodes. Described specifically, an electrode material film is first formed by sputtering or the like. Using a resist pattern as a mask, the electrode material film is then etched in a predetermined pattern although the illustration of this step is omitted in the figures. This etching is conducted by dry etching or wet etching. It is assumed to conduct wet etching in this embodiment. In this case, a mixed acid is used as an etchant. After completion of the etching, the resist pattern is stripped off.

It is to be noted that in this step, auxiliary wirings may be formed between the pixel electrodes formed in the reflective material layer 11a.

As illustrated in FIG. 2B, window insulating films 13 are next formed in such shapes that they cover the patterned reflective material layer 11a at peripheral edges thereof. Described specifically, after an insulating film of an organic material or a silicon-based inorganic material is formed, pixel openings 13a of the shape that the respective reflective material layers 11a are widely exposed at central parts thereof are formed as window insulating films 13 in the insulating film in a lithographic step. As an alternative, the window insulating films 13 may be formed as a resist pattern in a lithographic step.

When the auxiliary wirings are formed together with the reflective material layers 11a, the insulating film is patterned to expose the auxiliary wirings. Upon patterning the insulating film, the auxiliary wirings may be exposed at parts thereof and may be covered at the remaining parts thereof. As an alternative, the auxiliary wirings may be exposed at the entire parts thereof from the window insulating films 13.

During the above-described steps, the patterned reflective material layers 11a are naturally oxidized at surfaces thereof so that oxide films 11b are formed. These oxide films 11b are formed in the lithographic step upon formation of the reflective material layers 11, the lithographic steps upon performing the wet etching, stripping off the resist pattern and forming the window insulating films 13, and the step upon stripping off the resist. The oxide films 11b are formed, for example, with a thickness (optical thickness) of 2 nm or so.

As illustrated in FIG. 2C, thin metal films 11c are then formed such that they cover exposed surfaces of the reflective material layers 11a with the oxide films 11b formed thereon. Preferably, these thin metal films 11c can be formed by a vacuum process represented by vacuum evaporation or sputtering.

The thin metal films 11c may preferably cover the entire surfaces of the reflective material layers 11a exposed through the window insulating films 13, and may be formed extending onto the window insulating films 13. Preferably, however, the thin metal films 11c may be separated from the thin metal films 11c at the adjacent pixel portions on the window insulating films 13. Preferably, the thin metal films 11c may also be formed over the auxiliary wirings such that they are separated from the reflective material layers 11a.

By the above-described steps, lower electrodes 11 are obtained, each of which is composed of the reflective material layer 11a formed of the metal material, the oxide film 11b provided on the surface of the reflective material layer 11a, and the thin metal film 11c covering the reflective material layer 11a with the oxide film 11b provided thereon.

As illustrated in FIG. 2D, luminescence function layers 15 are then formed on the lower electrodes 11, respectively. The formation of the luminescence function layers 15 is assumed to be conducted in continuation with the formation of the thin metal films 11c that make up the respective lower electrodes 11. The term “in continuation with” as used herein means that the formation of the luminescence function layers 15 is conducted while maintaining an inert atmosphere (for example, a vacuum atmosphere) employed upon forming the thin metal films 11c.

The formation of such luminescence function layers 15 can be conducted, for example, color by color of the organic electroluminescent devices by a masked deposition process or a printing process. When auxiliary wirings are formed, it is preferred to avoid the arrangement of the luminescence function layers 15 over the auxiliary wirings.

Subsequently, an upper electrode 17 is formed on the luminescence function layers 15 and the window insulating films 13. The formation of the upper electrode 17 can be conducted by a process such as vacuum evaporation, sputtering or plasma CVD (Chemical Vapor Deposition). It is to be noted that, when auxiliary wirings are formed, the upper electrode 17 is connected to the auxiliary wirings.

In the above-described manner, a display device 20 is obtained with organic electroluminescent devices EL arranged on the TFT substrate 2. These organic electroluminescent devices EL include the lower electrode 11, the luminescence function layer 15 and the upper electrode 17.

In the above-described embodiment, the oxide film 11b on the surface of each reflective material layer 11a is covered by the thin metal film 11c. This thin metal film 11c, therefore, serves as a layer that makes up the outermost surface of the lower electrode 11 so that holes are injected from the thin metal film 11c into the luminescence function layer 15. As a consequence, in the construction that the thin metal film 11b is formed as a result of natural oxidation of the surface of the reflective material layer 11a, the efficiency of injection of holes from the high-reflectivity lower electrode 11 into the luminescence function layer 15 can be maintained high.

As a result, it is possible to achieve an improvement in the luminescence efficiency of a surface-emitting, organic electroluminescent device EL and a reduction in its drive voltage, and therefore, to achieve an improvement in its service life characteristics.

Such advantageous effects can also be obtained likewise even when the lower electrode 11 is formed as a cathode in the surface-emitting, organic electroluminescent device EL. Accordingly, the present invention can also be applied even when the lower electrode 11 is constructed as a cathode. In this design, it is only necessary to reverse the order of stacking of the respective layers which make up the luminescence function layer 15.

### <Panel Construction of Display Device>

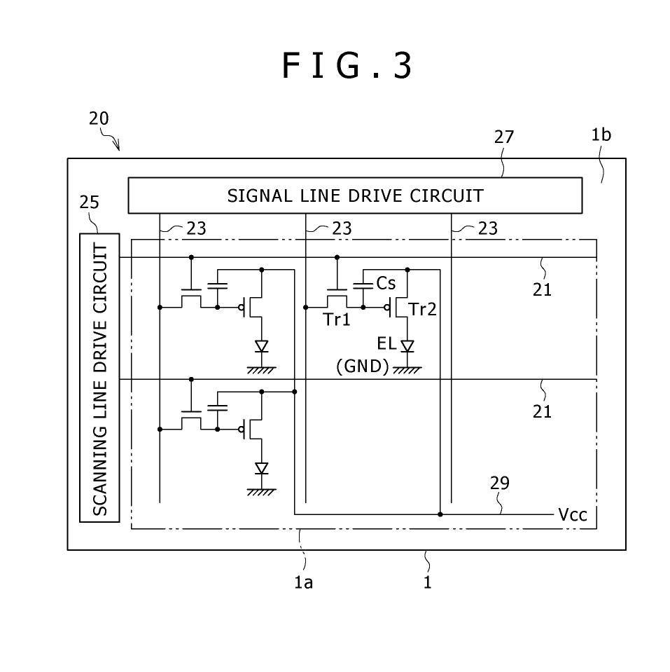

FIG. 3 is a schematic circuit construction diagram illustrating one example of the panel construction of the display device 20 constructed using the above-described organic electroluminescent devices EL.

As illustrated in the figure, a display area 1a and its peripheral area 1b are set on the substrate 1 with the organic electroluminescent devices EL arranged thereon in the display device 20. In the display area 1a, plural scanning lines 21 and plural signal lines 23 are formed horizontally and vertically, respectively, and corresponding to their intersections, pixels are arranged, respectively, so that the display area 1a is constructed as a pixel array area. Arranged in the peripheral area 1b, on the other hand, are a scanning line drive circuit 25 for scanning and driving the scanning lines 21 and a signal line drive circuit 27 for feeding video signals (in other words, input signals) to the signal lines 23 in correspondence to brightness information.

The pixel circuits arranged at the respective intersections between the scanning lines 21 and the signal lines 23 are each composed, for example, of a switching thin-film transistor Tr1, a driving thin-film transistor Tr2, a retention capacitor Cs, and the organic electroluminescent device EL. Each video signal, which has been written from the signal line 23 via the switching thin-film transistor Tr1 based on a drive by the scanning line drive circuit 25, is retained in the retention capacitor Cs, a current corresponding to the retained signal amount is fed from the driving thin-film transistor Tr2 to the organic electroluminescent device EL, and the organic electroluminescent device EL emits light at a brightness corresponding to the value of the current. It is to be noted that the driving thin-film transistor Tr2 and the retention capacitor Cs are connected to a common power supply line (Vcc) 29.

It is also to be noted that the above-described pixel circuit construction is merely illustrative. It is, therefore, possible to arrange a capacitor in the pixel circuit as needed, and to construct the pixel circuit with plural transistors. Further, one or more drive circuits can be added further to the peripheral area 1b as needed depending on modifications to the pixel circuit.

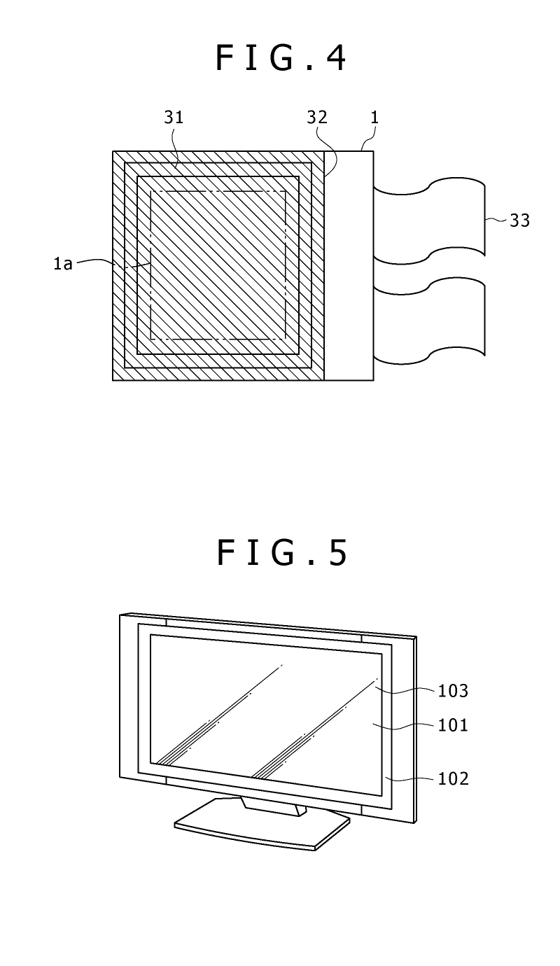

The above-described display device 20 according to the embodiment of the present invention can also be in the form of a module of sealed construction as shown in FIG. 4. For example, a sealing part 31 is arranged such that it surrounds the display area 1a as the pixel array area. Forming this sealing part 31 as an adhesive, the substrate 1 is bonded on an opposing element (sealing substrate 32) made of transparent glass or the like to fabricate a display module. This transparent sealing substrate 32 may be provided with a color filter, a protective film, a light-shielding film and/or the like. It is to be noted that the substrate 1 as a display module with the display area 1a formed may be provided with flexible printed substrates 33 for inputting/outputting signals or the like to the display area 1a (pixel array area) from the outside.

It is to be noted that the above-described organic electroluminescent device EL according to the embodiment of the present invention is not limited to a light-emitting device useful in an active matrix display device making use of a TFT substrate but may also be applicable as a light-emitting device useful in a passive-matrix display device and can bring about a similar advantageous effect (an improvement in long-term reliability).

### <Application Examples>

The above-described display device according to the embodiment of the present invention can also be applied as a display device in electronic equipment in various fields which display, as a picture image or video image, video signals inputted into the electronic equipment or video signals generated in the electronic equipment, such as various electronic equipment depicted in FIGS. 5 to 9G, for example, digital cameras, notebook-size personal computers, mobile terminal equipment such as cellular phones, and video cameras. A description will hereinafter be made about examples of the electronic equipment to which the present invention can be applied.

FIG. 5 is a perspective view of a television set to which the present invention can be applied. The television set according to this application example includes an image display screen 101 constructed of a front panel 102, a filter glass 103, etc., and can be manufactured by using the display device according to the embodiment of the present invention as the image display screen 101.

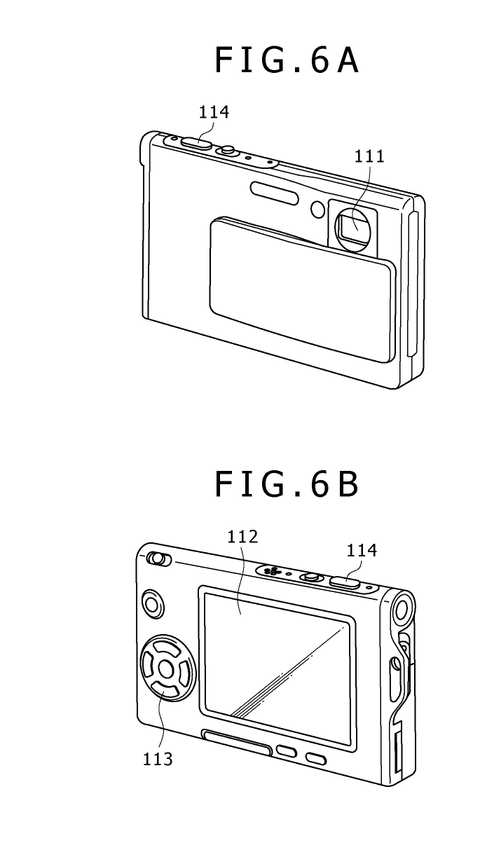

FIGS. 6A and 6B are perspective views of a digital camera to which the present invention can be applied. FIG. 6A is a perspective view as viewed from the front side, while FIG. 6B is a perspective view as viewed from the back side. The digital camera according to this application example includes a light-emitting unit 111 for flash light, a display 112, a menu selector 113, a shutter button 114, etc., and can be manufactured by using the display device according to the embodiment of the present invention as the display 112.

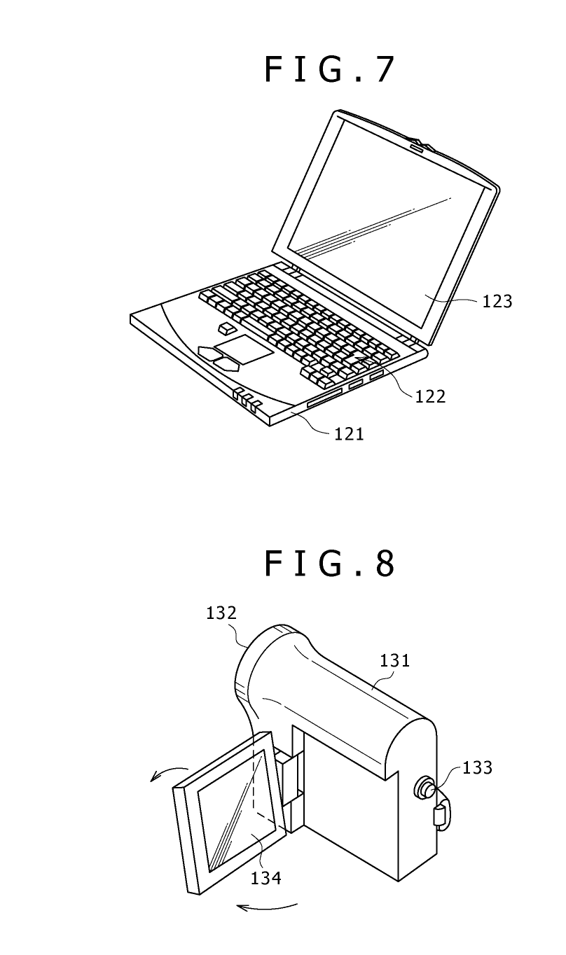

FIG. 7 is a perspective view showing a notebook-size personal computer to which the present invention can be applied. The notebook-size personal computer according to this application example includes a main body 121, a keyboard 122 to be operated upon inputting characters and the like, a display 123 for displaying images, etc., and can be manufactured by using the display device according to the embodiment of the present invention as the display 123.

FIG. 8 is a perspective view showing a video camera to which the present invention can be applied. The video camera according to this application example includes a main body 131, an object-shooting lens 132 in a front side, a start/stop switch 133 employed upon shooting, a display 134, etc., and can be manufactured by using the display device according to the embodiment of the present invention as the display 134.

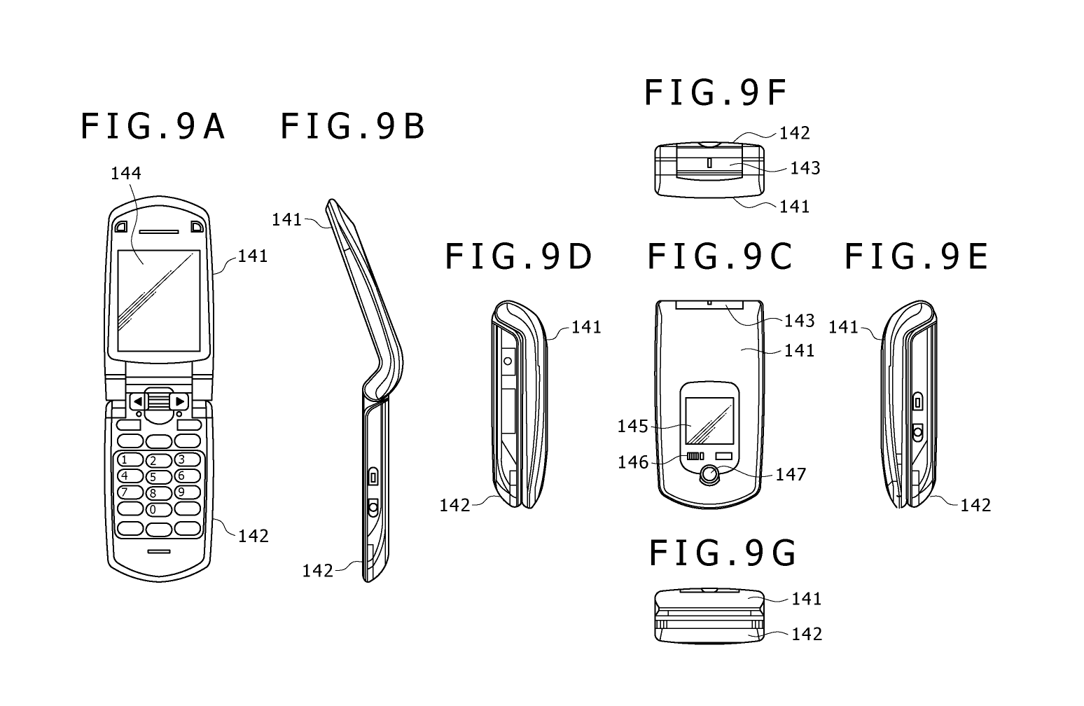

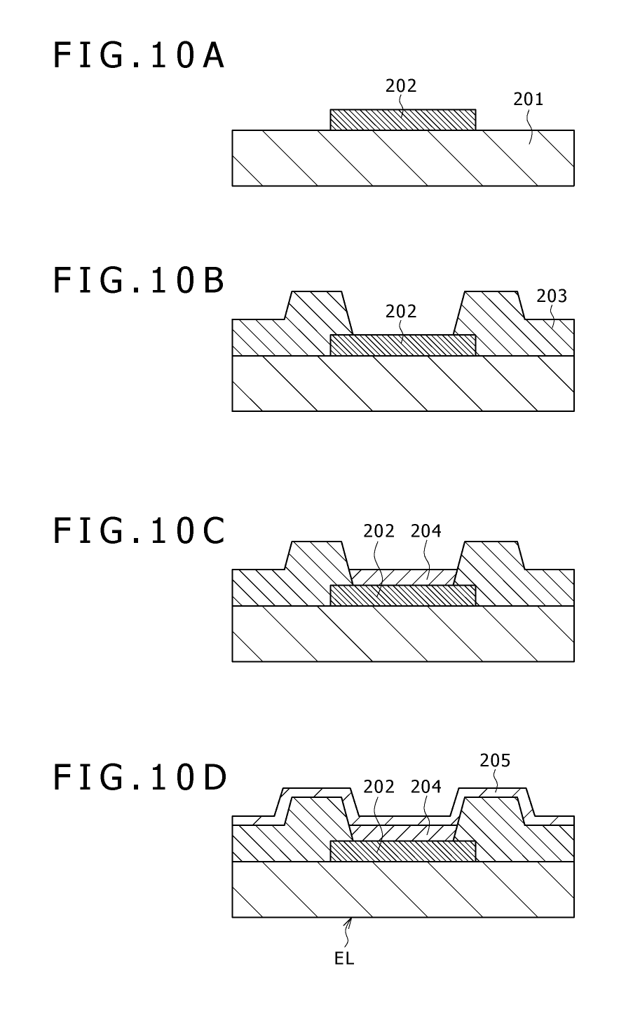

FIGS. 9A through 9G illustrate a mobile terminal equipment, specifically a cellular phone to which the present invention can be applied, in which FIG. 9A is its front view in an opened state, FIG. 9B is its side view in the opened state, FIG. 9C is its front view in a closed state, FIG. 9D is its left side view in the closed state, FIG. 9E is its right side view in the closed state, FIG. 9F is its top view in the closed state, and FIG. 9G is its bottom view in the closed state. The cellular phone according to this application example includes an upper casing 141, a lower casing 142, a connecting portion (hinge in this example) 143, a display 144, a sub-display 145, a picture light 146, a camera 147, etc., and can be manufactured by using display devices according to the embodiment of the present invention as the display 144 and sub-display 145.

### EXAMPLES

With reference to FIGS. 1A and 1B, a description will now be made of a fabrication procedure for the organic electroluminescent devices of Examples, to which the present invention was applied, and Comparative Examples, and their evaluation results will then be described. In the respective Examples and Comparative Examples, surface-emitting organic electroluminescent devices of cavity structures were fabricated. The materials employed for the respective layers in the respective Examples and Comparative Examples are shown below in Table 8.

TABLE 8

| | Lower electrode 11 | | | | | | |
|---|---|---|---|---|---|---|---|
| | Reflective | | | | | | |
| | material | Thin metal | Hole | Current | Drive | | Service |
| | layer 11a | film 11c | injection | efficiency | voltage | | life |
| | (anodes) | (thickness) | layer 15a | [cd/A] | [V] | Chromaticy | [hr] |
| Ex. 1 | Al | Cu 0.5 | Compound | 0.60 | 10.0 | 0.128, 0.109 | 103 |
| Ex. 2 | | Al 0.5 nm | (101) | 0.60 | 10.3 | 0.125, 0.116 | 100 |
| Ex. 3 | | Ag 0.5 nm | | 0.60 | 10.2 | 0.128, 0.107 | 100 |
| Ex. 4 | | Li 1.0 nm | | 0.60 | 10.2 | 0.129, 0.101 | 100 |
| Ex. 5 | | Cu 0.5 nm | Compound | 6.20 | 5.5 | 0.128, 0.107 | 300 |
| Ex. 6 | | Al 0.5 nm | (102) | 6.60 | 5.3 | 0.128, 0.101 | 400 |
| Ex. 7 | | Ag 0.5 nm | | 6.50 | 5.3 | 0.128, 0.107 | 450 |
| Ex. 8 | | MgAg 0.5 nm | | 6.30 | 5.3 | 0.129, 0.101 | 400 |
| Ex. 9 | | Al 0.5 nm | MoO₃ | 6.25 | 5.1 | 0.128, 0.107 | 500 |
| Comp. Ex. 1 | | — | Compound | 0.30 | 19.3 | 0.128, 0.101 | 0.1 |
| | | | (101) | | | | |
| Comp. Ex. 2 | | | Compound | 6.30 | 7.5 | 0.128, 0.103 | 250 |
| Comp. Ex. 3 | ITO | | (102) | 1.80 | 5.1 | 0.137, 0.136 | 280 |
| Comp. Ex. 4 | Al | | MoO₃ | 5.80 | 8.0 | 0.128, 0.103 | 200 |
| Comp. Ex. 5 | ITO | | Compound | 1.00 | 5.1 | 0.128, 0.103 | 30 |
| | | | (101) | | | | |

On substrates 2 made of glass plates of 30 mm×30 mm, reflective material layers (anodes) 11a which form lower electrodes 11 were formed with a thickness of 200 nm by using the materials shown in Table 8, respectively. It is to be noted that in Comparative Examples 3 and 5, transparent electrodes made of ITO and equivalent to the reflective material layers (anodes) 11a were formed, respectively.

By a photolithographic step making use of a polyimide resin, the reflective material layers 11a were then masked by window insulating films 13 at areas other than light-emitting regions of 2 mm×2 mm to fabricate cells for organic electroluminescent devices.

It is to be noted that at that time point, Al₂O₃ films of about 2 nm in thickness had been formed as oxide films 11b on the surfaces of the respective reflective material layers 11a.

In the respective Examples, thin metal films 11c were formed with the corresponding materials to the corresponding thicknesses shown in Table 8. In the respective Comparative Examples, on the other hand, the formation of the thin metal films 11c was omitted.

Subsequently, hole injection layers 15a were formed to a thickness of 10 nm with the respective materials shown in Table 8.

Hole transport layers 15b were then formed to a thickness of 130 nm (at an evaporation rate of from 0.2 to 0.4 nm/sec) with the respective materials shown in Table 8. It is to be noted that the compound (101) and compound (102) shown in Table 8 have the following structures:

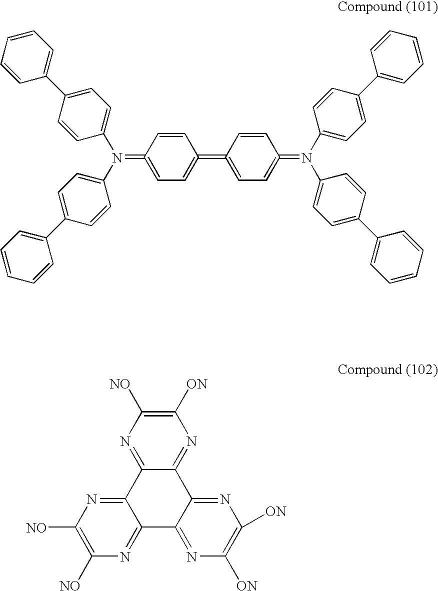

In the respective Examples and Comparative Examples, organic light-emitting layers 15c made of a common material were next formed. Using 9-(2-naphthyl)-10-[4-(1-naphthyl)phenyl]anthracene (host A) as a host and a blue-light-emitting dopant compound, N,N,N′N′-tetra(2-naphthyl)-4,4′-diaminostilbene (dopant B), the organic light-emitting layers 15c were formed at a dopant concentration of 5% in terms of thickness ratio with a thickness of 36 nm by vacuum evaporation.

In the respective Examples and Comparative Examples, electron transport layers 15d made of a common material were then formed. As the electron transport layers 15d, Alq3 was formed with a thickness of 10 nm (deposition rate: 0.1 nm/sec) by vacuum evaporation.

In each of the Examples and Comparative Examples, a luminescent function layer 15 includes layers from the hole injection layer 15a to the electron transport layer 15d.

LiF was subsequently formed, as a first layer of an upper electrode 17 to be used as a cathode, with a thickness of about 0.3 nm (deposition rate: up to 0.01 nm/sec) by vacuum evaporation. MgAg was then formed, as a second layer, with a thickness of 10 nm by vacuum evaporation to arrange the upper electrode 17 as a double-layered structure.

### <Evaluation Results>

With respect to each of the organic electroluminescent devices EL of the Examples and Comparative Examples fabricated as described above, its current efficiency (cd/A), drive voltage (V) and chromaticy were measured when driven at a current density of 10 mA/cm². Also measured as a service life was the time in which the relative brightness dropped to 0.9 while being driven at a constant current of 125 mA/cm² when the initial brightness was assumed to be 1. These measurement results are shown above in Table 8.

From the results shown in Table 8, a comparison between Examples 1 to 4 and Comparative Example 1, in which the reflective material layer 11a and hole transport layer 15a were formed with the same materials, indicates that an improvement in current efficiency, a reduction in drive voltage and an improvement in service life were achieved in Examples 1 to 4, in which the thin metal films 11c were formed, irrespective of the material of the thin metal films 11c. Accordingly, the advantageous effects available from the arrangement of the thin metal films 11c have been confirmed.

Similar results were also found from a comparison between Examples 5 to 8 and Comparative Example 2, and also from a comparison between Example 9 and Comparative Example 4. The advantageous effects available from the arrangement of the thin metal films 11c have also been confirmed.

Among the Examples in which the thin metal films 11c were arranged, Examples 5 to 8 in which the material of the formula (1) suited for the hole injection layers 15a was used to achieve an improvement in current efficiency, a reduction in drive voltage and an improvement in service life in comparison with Examples 1-4 and 9 in which the material of the formula (1) was not used. Accordingly, the advantageous effects available from the construction of the hole injection layers 15a with the material of the formula (1) have been confirmed.

It has also been confirmed that, in Examples 1 to 9 in each of which the lower electrode 11 was provided with the reflective material layers 11a to form a cavity structure, a blue chromaticy of still higher purity was obtained than Comparative Examples 3 and 5 in each of which transparent electrodes (ITO) were formed at places corresponding to the reflective material layers 11a.

It should be understood by those skilled in the art that various modifications, combinations, sub-combinations and alterations may occur depending on design requirements and other factors insofar as they are within the scope of the appended claims or the equivalents thereof.

What is claimed is:

1. An organic electroluminescent device comprising a substrate, a lower electrode, a luminescence function layer including an organic light-emitting layer, and an upper electrode stacked in this order to emit light, which has been generated in said organic light-emitting layer, out of said upper electrode, wherein
said lower electrode includes a reflective material layer comprised essentially of metal, an oxide film provided on a surface of said reflective material layer, and a thin metal film provided over said oxide film.

2. The device of claim 1, wherein
said light generated in said organic light-emitting layer is emitted out of said upper electrode after resonated between said lower electrode and said upper electrode.

3. The device of claim 1, wherein
said reflective material layer in said lower electrode is used as an anode,
said luminescence function layer has a hole injection layer at said lower electrode side, and
said hole injection layer includes a material represented by the following formula (1): 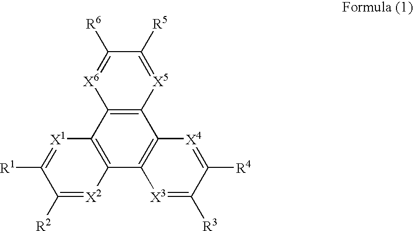
wherein R¹ to R⁶ each independently represent a hydrogen atom, or a substituent selected from a halogen atom, a hydroxyl group, an amino group, an arylamino group, a substituted or unsubstituted carbonyl group having not greater than 20 carbon atoms, a substituted or unsubstituted carbonyl ester group having not greater than 20 carbon atoms, a substituted or unsubstituted alkyl group having not greater than 20 carbon atoms, a substituted or unsubstituted alkenyl group having not greater than 20 carbon atoms, a substituted or unsubstituted alkoxyl group having not greater than 20 carbon atoms, a substituted or unsubstituted aryl group having not greater than 30 carbon atoms, a substituted or unsubstituted heterocyclic group having not greater than 30 carbon atoms, a nitrile group, a nitro group, a cyano group, or silyl group; adjacent R^{m} (m: 1 to 6) may be fused together to form ring structures together with the associated carbon atoms of the corresponding 6-membered rings, respectively; and X¹ to X⁶ each independently represent a carbon or nitrogen atom.

4. The device of claim 1 comprising
an insulating film provided over said substrate such that said insulating film covers said lower electrode at peripheral edges thereof.

5. A fabrication process of an organic electroluminescent device, comprising:
a first step of forming a reflective material layer in a predetermined pattern comprised essentially of metal on a substrate;
a second step of forming a thin metal film and a luminescence function layer in this order on said reflective material layer in an inert atmosphere; and
a third step of forming an upper electrode on said luminescence function layer.

6. The process of claim 5 further comprising
between said first step and said second step, a step of forming an insulating film in a pattern that a insulating film covers said reflective material layer at peripheral edges thereof.

7. A display device provided with a plurality of organic electroluminescent devices arrayed on a substrate and each comprising a lower electrode, a luminescence function layer including an organic light-emitting layer, and an upper electrode stacked in this order to emit light generated in said organic light-emitting layer, out of said upper electrode, wherein
said lower electrode includes a reflective material layer comprised essentially of metal, an oxide film provided on a surface of said reflective material layer, and a thin metal film provided over said oxide film.

8. The device of claim 7 comprising
insulating films provided over said substrate such that said insulating films cover the corresponding lower electrodes in said plurality of organic electroluminescent devices at peripheral edges of said corresponding lower electrodes.

9. A fabrication process of a display device, comprising:
a first step of forming a plurality of reflective material layers in a predetermined pattern comprised essentially of metal on a substrate;
a second step of forming thin metal films and luminescence function layers in this order on the respective reflective material layers in an inert atmosphere; and
a third step of forming upper electrodes on the respective luminescence function layers.

10. The process of claim 9 further comprising
between said first step and said second step, a step of forming insulating films in a pattern so that said insulating films cover the respective reflective material layers at peripheral edges thereof.
